(19) United States
(12) Patent Application Publication
(10) Pub. No.: US 2015/0062815 A1
(43) Pub. Date: Mar. 5, 2015

(54) COOLING FAN SYSTEM AND COMMUNICATION EQUIPMENT

(71) Applicant: HITACHI METALS, LTD., Tokyo (JP)

(72) Inventor: Takuya NOMURA, Tsuchiura (JP)

(21) Appl. No.: 14/315,493

(22) Filed: Jun. 26, 2014

(30) Foreign Application Priority Data
Aug. 30, 2013 (JP) 2013-179479

(51) Int. Cl. H05K 7/20

(52) U.S. Cl. CPC H05K 7/20209; H05K 7/20136
USPC 361/695; 165/244; 165/247

(57) ABSTRACT

A cooling fan system includes at least one fan unit including a cooling fan and a controller for controlling the cooling fan, a management unit including a fan control section that controls the controller of the fan unit, and a circuit directly connecting the management unit to the cooling fan so as to allow the cooling fan to be controlled directly by the fan control section. The fan control section includes a malfunction detecting section to detect malfunction of the fan unit and a forced control section that directly controls the cooling fan and carries out a forced control to forcibly rotate the cooling fan at a higher rotational speed than that during normal operation when the malfunction detecting section detects the malfunction of the fan unit.

The present application is based on Japanese patent application No. 2013-179479 filed on Aug. 30, 2013, the entire contents of which are incorporated herein by reference.

### BACKGROUND OF THE INVENTION

1. Field of the Invention

The invention relates to a cooling fan system and a communication equipment using the cooling fan system.

2. Description of the Related Art

In recent years, according to the increase of signal processing speed, communication equipment tends to consume more power as a whole and generate more heat therein.

In order to prevent the malfunction of communication equipment caused by heat, it is desired that the cooling fan system installed in the communication equipment is to keep the cooling capability for a certain period (i.e., a time need for replacing the defective part) even when the cooling fan is out of order.

A conventional cooling system is known in which plural fan units each having plural cooling fans and a controller are mounted and the fan units are each controlled by a fan control section in a management unit.

In the cooling fan system, even when one cooling fan in the fan unit is out of order, the cooling capability can be kept by controlling the rotational speed of other cooling fan in the unit or the rotational speed of cooling fan of other fan unit to be higher than during normal operation. In addition, the cooling fan system can be replaced in units of the fan unit and it is thus possible to reduce working hours for replacement.

The related art to the invention may include JP-A-2011-066366.

### SUMMARY OF THE INVENTION

The cooling fan system may cause the problem that a sufficient cooling capability may not be kept since the cooling fan in one fan unit stops operating when the controller of the fan unit is out of order.

It is an object of the invention to provide a cooling fan system that can keep the sufficient cooling capability even when the controller of one fan unit is out of order, as well as a communication equipment using the cooling fan system.

(1) According to one embodiment of the invention, a cooling fan system comprises:

at least one fan unit comprising a cooling fan and a controller for controlling the cooling fan;

a management unit comprising a fan control section that controls the controller of the fan unit; and

a circuit directly connecting the management unit to the cooling fan so as to allow the cooling fan to be controlled directly by the fan control section,

wherein the fan control section comprises a malfunction detecting section to detect malfunction of the fan unit and a forced control section that directly controls the cooling fan and carries out a forced control to forcibly rotate the cooling fan at a higher rotational speed than that during normal operation when the malfunction detecting section detects the malfunction of the fan unit.

In the above embodiment (1) of the invention, the following modifications and changes can be made.

(i) The forced control section is configured to forcibly rotate the cooling fan at the maximum rotational speed during the forced control.

(ii) The fan control section further comprises a temperature determination section that generates a temperature alarm when temperature of a device to be cooled becomes the preset upper limit temperature or more, and

wherein the forced control section is configured to carry out the forced control when the temperature determination section generates the temperature alarm.

(iii) The fan control section further comprises an attachment/detachment detecting section to detect attachment/detachment of the fan unit, and

wherein the forced control section is configured to carry out the forced control when the attachment/detachment detecting section detects removal of the fan unit.

(iv) The forced control section is configured to terminate the forced control of the removed fan unit when the attachment/detachment detecting section detects removal of the fan unit during the forces control.

(v) The fan control section is configured to send a target rotational speed of the cooling fan to the controller such that the controller controls the cooling fan to rotate at a same rotational speed as the target rotational speed received from the fan control section, wherein the controller comprises a malfunction informing section to inform the fan control section that malfunction occurs in the fan unit when the actual rotational speed is different from the target rotational speed of the cooling fan, and

wherein the fan control section is configured to send a rotational speed during the forced control, as the target rotational speed, to the controller of the fan unit when the malfunction of the fan unit is detected during the forced control.

(2) According to another embodiment of the invention, a communication equipment comprises:

a cooling fan system that comprises at least one fan unit comprising a cooling fan and a controller for controlling the cooling fan, a management unit comprising a fan control section that controls the controller of the fan unit, and a circuit directly connecting the management unit to the cooling fan so as to allow the cooling fan to be controlled directly by the fan control section,

wherein the fan control section comprises a malfunction detecting section to detect malfunction of the fan unit and a forced control section that directly controls the cooling fan and carries out a forced control to forcibly rotate the cooling fan at a higher rotational speed than that during normal operation when the malfunction detecting section detects the malfunction of the fan unit.

### EFFECTS OF THE INVENTION

According to one embodiment of the invention, a cooling fan system can be provided that can keep the sufficient cooling capability even when the controller of one fan unit is out of order, as well as a communication equipment using the cooling fan system.

### BRIEF DESCRIPTION OF THE DRAWINGS

Next, the present invention will be explained in more detail in conjunction with appended drawings, wherein:

FIG. 1 is a schematic block diagram illustrating a cooling fan system in an embodiment of the present invention;

FIG. 2 is a circuit diagram illustrating a circuit which connects a management unit to cooling fans in the cooling fan system of FIG. 1;

FIG. 3 is a flow chart showing a control flow of the cooling fan system of FIG. 1; and

FIG. 4 is a flow chart showing a control flow of forced control in FIG. 3.

### DETAILED DESCRIPTION OF THE PREFERRED EMBODIMENTS

The embodiment of the invention will be described below in conjunction with the appended drawings.

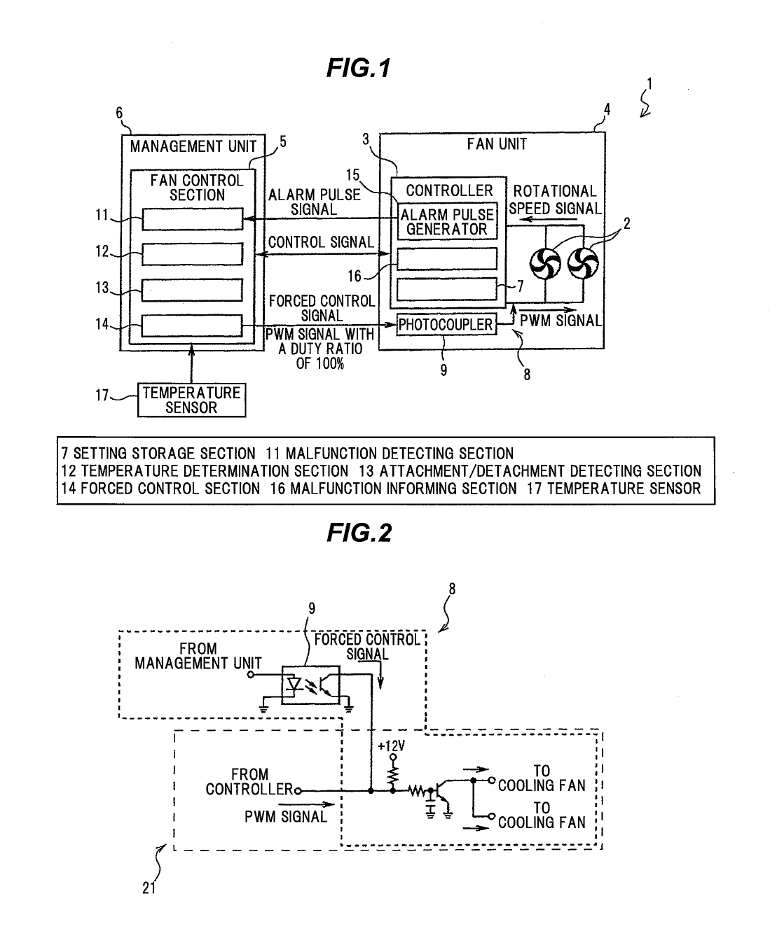

FIG. 1 is a schematic block diagram illustrating a cooling fan system in the present embodiment.

As shown in FIG. 1, a cooling fan system 1 is provided with one or more fan units 4 each having cooling fans 2 and a controller 3 for controlling the cooling fans 2, and a management unit 6 having a fan control section 5 which controls the controller 3 of the fan unit 4.

The cooling fan system 1 is installed in, e.g., a communication equipment such as Ethernet switch (Ethernet is a registered trademark) to cool the inside thereof.

The fan unit 4 is provided with two cooling fans 2. Although only one fan unit 4 is shown in FIG. 1 to simplify the drawing, plural (e.g., four or five) fan units 4 are practically connected to the management unit 6.

The cooling fan 2 is provided with a sensor (not shown) for detecting the rotational speed thereof and a rotational speed signal output from the sensor is input to the controller 3.

The controller 3 sends PWM (Pulse Width Modulation) signals to the cooling fans 2 and a duty ratio of the PWM signals is adjusted to control the rotational speed of the cooling fans 2. The controller 3 is provided with a setting storage section 7 which stores various settings such as a target rotational speed of the cooling fan 2.

The controller 3 of the fan unit 4 and the fan control section 5 of the management unit 6 are connected so that control signals can be sent and received to each other. The fan control section 5 is configured to send a control signal to the controller 3 to control the controller 3 and to control the cooling fans 2 via the controller 3.

In more detail, the fan control section 5 is configured to send a target rotational speed of the cooling fan 2 to the controller 3 by means of control signal and the controller 3 is configured to store the received target rotational speed of the cooling fan 2 in the setting storage section 7 and also to control the cooling fan 2 to rotate at the same rotational speed as the target rotational speed stored in the setting storage section 7. The controller 3 is configured to carry out feedback control to adjust a duty ratio of the PWM signal so that a rotational speed signal from the cooling fan 2 is consistent with the target rotational speed.

The cooling fan system 1 in the present embodiment is provided with a circuit 8 directly connecting the management unit 6 to the cooling fans 2, i.e., it is configured that the management unit 6 and the cooling fans 2 are connected without interposition of the controller 3 and the cooling fans 2 can be controlled directly by the fan control section 5.

As shown in FIGS. 1 and 2, the circuit 8 is configured such that a signal line extending from the management unit 6 is directly connected, via a photocoupler 9, to a conventionally-provided PWM signal transmission circuit 21 located from the controller 3 to the cooling fans 2. Although the photocoupler 9 is used here to suppress noise contamination, etc., the photocoupler 9 may be eliminated.

Furthermore, in the cooling fan system 1 of the present embodiment, the fan control section 5 is provided with a malfunction detecting section 11 to detect malfunction of the fan unit 4 and a forced control section 14 which directly controls the cooling fans 2 via the circuit 8 and carries out forced control to forcibly rotate the cooling fans 2 at a higher rotational speed than during normal operation when the malfunction detecting section 11 detects malfunction of the fan unit 4.

In the present embodiment, it is configured that an alarm pulse (e.g., a clock signal of 25 kHz) is generated by an alarm pulse generator 15 provided on the controller 3 of the fan unit 4 and is transmitted to the management unit 6, and the malfunction detecting section 11 judges that malfunction is occurring in the fan unit 4 when the alarm pulse from the concerned fan unit 4 is not detected for a predetermined period of time, and then generates a fan failure alarm.

In addition, the controller 3 has a malfunction informing section 16 which causes the alarm pulse generator 15 to stop generating the alarm pulse when malfunction of the fan unit 4 is detected and thereby informs the fan control section 5 that malfunction is occurring in fan unit 4.

The malfunction informing section 16 is configured to cause the alarm pulse generator 15 to stop generating the alarm pulse when the real rotational speed (the actual rotational speed) becomes different from the target rotational speed stored in the setting storage section 7, e.g., when an absolute value of a difference between (or a ratio of) the target rotational speed and the actual rotational speed reaches a predetermined threshold value or more.

In addition, the malfunction informing section 16 is configured to cause the alarm pulse generator 15 to stop generating the alarm pulse also when some malfunction occurs in the controller 3. Since alarm pulse generation by the alarm pulse generator 15 is generally stopped when the controller 3 completely breaks down, it is possible to detect malfunction of the fan unit 4 including failure of the controller 3 based on presence/absence of the alarm pulse.

When the malfunction detecting section 11 detects malfunction of the fan unit 4, i.e., when the malfunction detecting section 11 generates a fan failure alarm, the forced control section 14 outputs a forced control signal, via the circuit 8, to the cooling fans 2 of all fan units 4 including the fan unit 4 of which malfunction has been detected. In the present embodiment, the forced control section 14 is configured to send a PWM signal with a duty ratio of 100% as a forced control signal and thereby to forcibly rotate the cooling fans 2 at the maximum rotational speed during the forced control.

Thus, even when, e.g., one of the cooling fans 2 of the fan unit 4 fails to operate properly, it is possible to maintain cooling capability by rotating the properly-operating cooling fan 2 of the concerned fan unit 4 and cooling fans 2 of other fan units 4 at the maximum rotational speed.

In addition, even when the controller 3 breaks down, it is possible to maintain cooling capability by rotating the cooling fans 2 of the fan unit 4 mounting the broken controller 3 at the maximum rotational speed.

Note that, for carrying out the forced control, it is necessary to preliminarily inform the controller 3 that the forced control is carried out. This is because the forced control carried out without giving information to the controller 3 causes the cooling fans 2 to rotate at a different rotational speed from the target rotational speed stored in the setting storage section 7 of the controller 3, resulting in that the malfunction informing section 16 informs the fan control section 5 that malfunction is occurring even though the forced control is carried out in a normal manner. In other words, the forced control carried out without giving information to the controller 3 leads to a so-called state inconsistency in which control carried out by the fan control section 5 is different from that by the controller 3, and a fan failure alarm is thus generated even though the forced control is carried out in a normal manner.

Thus, in the present embodiment, to carry out the forced control, the forced control section 14 sends a control signal to preliminarily inform the controller 3 that the forced control is carried out. Once the controller 3 receives the control signal informing that the forced control is carried out, the controller 3 stores this information in the setting storage section 7. As a result, the malfunction informing section 16 informs the fan control section 5 that malfunction is occurring only when operation of the fan unit 4 during the forced control is not normal.

In the meantime, detection of malfunction of the fan unit 4 during the forced control means that the forced control is not carried out in a normal manner even though the forced control signal is sent, and it is considered that the circuit 8 including the photocoupler 9 fails to operate properly. Therefore, in the present embodiment, the forced control section 14 is configured so that the rotational speed during the forced control (the maximum rotational speed, in this case) is transmitted as the target rotational speed to the controller 3 of the fan unit 4 by means of the control signal when malfunction of the fan unit 4 is detected during the forced control.

For the fan unit 4 causing the fan failure alarm generated as a trigger to initiate the forced control, the fan failure alarm may be generated due to, e.g., failure of the cooling fan 2 or the controller 3 even after initiation of the forced control. Thus, it is preferable to configure the forced control section 14 such that, when the forced control is initiated due to malfunction of the fan unit 4, the forced control of the fan unit 4 of which malfunction has been detected is continued even if malfunction is detected during the forced control.

The fan control section 5 is further provided with a temperature determination section 12 which generates a temperature alarm when temperature of a communication equipment to be cooled becomes the preset upper limit temperature or more. The forced control section 14 is configured to forcibly control all fan units 4 when the temperature determination section 12 generates the temperature alarm. A temperature sensor 17 for measuring temperature inside the communication equipment is connected to the management unit 6 to generate an alarm when the output value of the temperature sensor 17 is the preset upper limit temperature (e.g., 50° C.) or more.

In addition, the fan control section 5 is further provided with a attachment/detachment detecting section 13 which detects attachment/detachment of the fan units 4. The forced control section 14 is configured to carry out the forced control when the attachment/detachment detecting section 13 detects removal of the fan units 4.

In the present embodiment, a predetermined voltage is applied to an attachment/detachment detecting terminal (not shown) which is grounded in the fan unit 4 and to be a ground potential when the fan unit 4 is attached, and the attachment/detachment detecting section 13 detects attachment/detachment of the fan units 4 based on a variation in potential of the attachment/detachment detecting terminal. Note that, the configuration to detect attachment/detachment of the fan unit 4 is not specifically limited.

In the meantime, if the forced control signal is output to the fan unit 4 of which removal is detected, information of the forced control is not given but the forced control is carried out when a replacement fan unit 4 is installed and this causes the cooling fans 2 to rotate at the maximum rotational speed, which results in that the malfunction informing section 16 judges that malfunction is occurring in the fan unit 4. Therefore, in the present embodiment, the forced control section 14 is configured not to output the forced control signal to the fan unit 4 of which removal has been detected.

The similar problem occurs when the fan unit 4 is replaced during the forced control. Therefore, in the present embodiment, the forced control section 14 is configured to stop sending the forced control signal to the fan unit 4 of which removal has been detected, and to thereby terminate the forced control of this fan unit 4 when the attachment/detachment detecting section 13 detects removal of the fan unit 4 during the forced control.

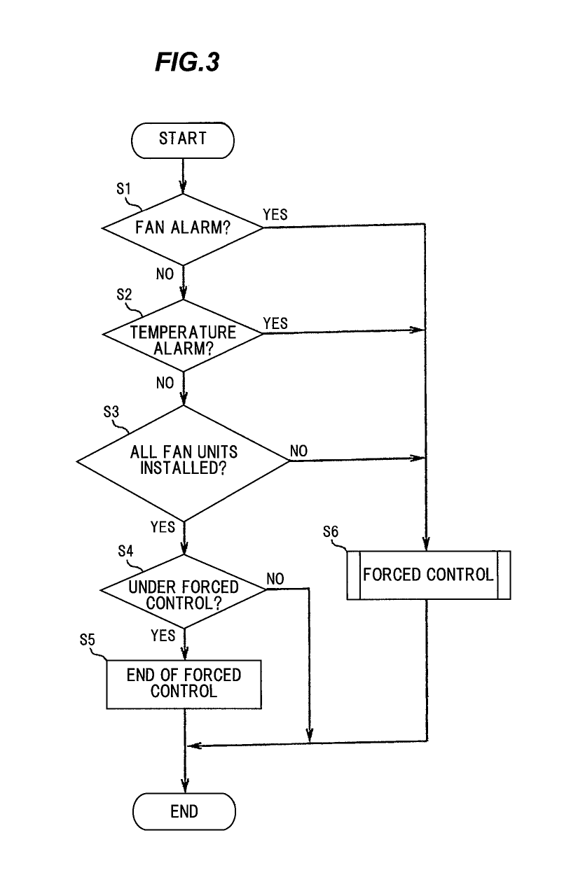

Next, a control flow of the cooling fan system 1 will be described. The cooling fan system 1 is configured to repeat the control flow shown in FIG. 3.

As shown in FIG. 3, firstly, the forced control section 14 judges in Step S1 whether or not the malfunction detecting section 11 is generating a fan failure alarm. When the judgment in Step S1 is YES, the process proceeds to the forced control in Step S6.

When judgment in Step S1 is NO, the forced control section 14 judges in Step S2 whether or not the temperature determination section 12 is generating a temperature alarm. When the judgment in Step S2 is YES, the process proceeds to the forced control in Step S6.

When judgment in Step S2 is NO, the forced control section 14 judges in Step S3 whether or not the attachment/detachment detecting section 13 has detected installation of all fan units 4. When the judgment in Step S3 is NO, the process proceeds to the forced control in Step S6.

When the judgment in Step S3 is YES, the forced control section 14 judges in Step S4 whether or not the forced control is being carried out. When the judgment in Step S4 is YES, the forced control signals to all fan units 4 are stopped in Step S5 to cancel information of the forced control, thereby terminating the forced control. When judgment in Step S4 is NO, the process is ended directly.

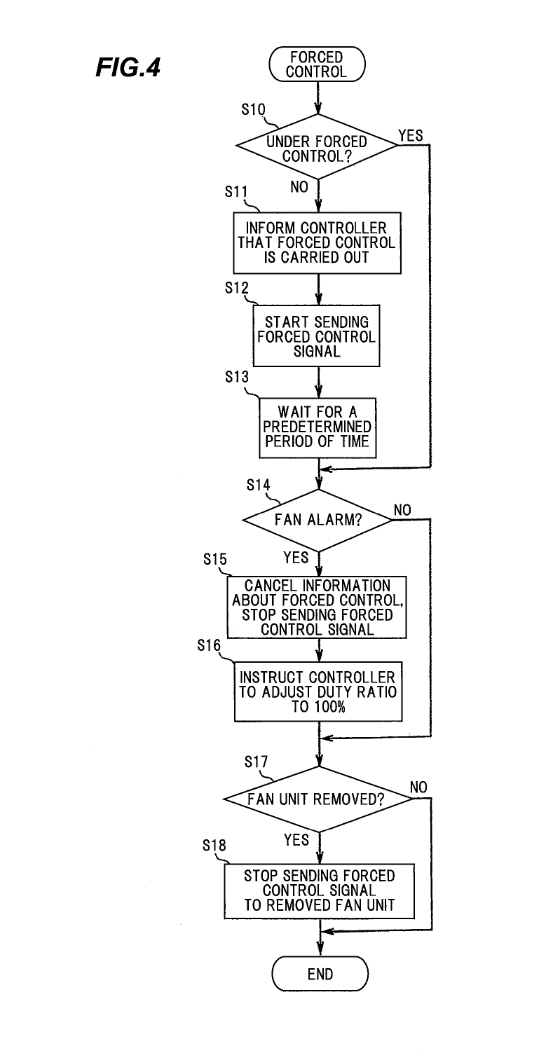

In the forced control of Step S6, firstly, the forced control section 14 judges in Step S10 whether or not the forced control is being carried out, as shown in FIG. 4. When the judgment in Step S10 is YES, the process proceeds to Step S14.

When the judgment in Step S10 is NO, the forced control section 14 sends control signals in Step S11 to inform the controllers 3 of all fan units 4 that the forced control is being carried out, and then starts sending the forced control signal in Step S12. In Step S12, when the forced control is initiated due to removal of the fan unit 4, the forced control signal is not sent to the removed fan unit 4. Then, after waiting for an increase of the rotational speed of the cooling fans 2 for a predetermined period of time in Step S13, the process proceeds to Step S14.

In Step S14, the forced control section 14 judges whether or not the malfunction detecting section 11 is generating a fan failure alarm. Note that, in Step S14, when the forced control is initiated by the fan failure alarm, the fan unit 4 causing the fan failure alarm is eliminated from the objects to be judged. When the judgment in Step S14 is NO, the process proceeds to Step S17.

When the judgment in Step S14 is YES, it indicates that the forced control is not carried out in a normal manner and failure of the circuit 8 is suspected. Thus, after cancelling information of the forced control to the fan unit 4 causing the fan failure alarm and stopping sending the forced control signal in Step S15, the controller 3 is instructed by the control signal to adjust the duty ratio of the PWM signal to be sent to the cooling fan 2 to 100% (i.e., the maximum rotational speed) in Step S16. After that, the process proceeds to Step S17.

In Step S17, the forced control section 14 judges whether or not the attachment/detachment detecting section 13 has detected removal of the fan unit 4. When the judgment in Step S7 is YES, the forced control signal to the removed fan unit 4 is stopped and the process is then ended in Step S18. When judgment in Step S17 is NO, the process is ended directly.

As described above, the cooling fan system 1 in the present embodiment is provided with the circuit 8 directly connecting the management unit 6 to the cooling fans 2 and is configured that the cooling fans 2 can be controlled directly by the fan control section 5 which is provided with the malfunction detecting section 11 to detect malfunction of the fan unit 4 and the forced control section 14 which directly controls the cooling fans 2 and carries out the forced control to forcibly rotate the cooling fans 2 at a higher rotational speed than during normal operation when the malfunction detecting section 11 detects malfunction of the fan unit 4.

This configuration allows the cooling fans 2 to be forcibly rotated by the management unit 6 even if the controller 3 fails to operate properly. In other words, it is possible to realize the cooling fan system 1 which can maintain sufficient cooling capability even if the controller 3 of the fan unit 4 fails to operate properly.

As a result, it is possible to maintain cooling capability until replacement of the malfunctioning fan unit 4 is completed, which results in that failure of the communication equipment mounting the cooling fan system 1 caused by insufficient cooling is prevented.

It should be noted that the present invention is not intended to be limited to the above-mentioned embodiment and the various kinds of modification can be made without departing from the gist of the present invention.

For example, although, the control signal is used in the embodiment to inform that the forced control is carried out, it is not limited thereto. The forced control signal per se may be used to inform that the forced control is carried out.

In addition, also the case of mounting the cooling fan system 1 on the communication equipment has been described in the embodiment, the invention is applicable not only to communication equipment but also to any electric/electronic devices which need to be cooled.

Furthermore, although the forced control section 14 in the embodiment is configured to stop sending the forced control signal to the fan unit 4 of which removal has been detected, it is not limited thereto. The forced control section 14 may be configured not to stop sending the forced control signal to the removed fan unit 4 and to newly send a control signal to a new fan unit 4 to inform that the forced control is carried out when installation of the new fan unit 4 is detected.

Although the invention has been described with respect to the specific embodiment for complete and clear disclosure, the appended claims are not to be therefore limited but are to be construed as embodying all modifications and alternative constructions that may occur to one skilled in the art which fairly fall within the basic teaching herein set forth.

What is claimed is:

1. A cooling fan system, comprising:
at least one fan unit comprising a cooling fan and a controller for controlling the cooling fan;
a management unit comprising a fan control section that controls the controller of the fan unit; and
a circuit directly connecting the management unit to the cooling fan so as to allow the cooling fan to be controlled directly by the fan control section,
wherein the fan control section comprises a malfunction detecting section to detect malfunction of the fan unit and a forced control section that directly controls the cooling fan and carries out a forced control to forcibly rotate the cooling fan at a higher rotational speed than that during normal operation when the malfunction detecting section detects the malfunction of the fan unit.

2. The cooling fan system according to claim 1, wherein the forced control section is configured to forcibly rotate the cooling fan at the maximum rotational speed during the forced control.

3. The cooling fan system according to claim 1, wherein the fan control section further comprises a temperature determination section that generates a temperature alarm when temperature of a device to be cooled becomes the preset upper limit temperature or more, and
wherein the forced control section is configured to carry out the forced control when the temperature determination section generates the temperature alarm.

4. The cooling fan system according to claim 1, wherein the fan control section further comprises an attachment/detachment detecting section to detect attachment/detachment of the fan unit, and
wherein the forced control section is configured to carry out the forced control when the attachment/detachment detecting section detects removal of the fan unit.

5. The cooling fan system according to claim 4, wherein the forced control section is configured to terminate the forced control of the removed fan unit when the attachment/detachment detecting section detects removal of the fan unit during the forces control.

6. The cooling fan system according to claim 1, wherein the fan control section is configured to send a target rotational speed of the cooling fan to the controller such that the controller controls the cooling fan to rotate at a same rotational speed as the target rotational speed received from the fan control section,
wherein the controller comprises a malfunction informing section to inform the fan control section that malfunction occurs in the fan unit when the actual rotational speed is different from the target rotational speed of the cooling fan, and
wherein the fan control section is configured to send a rotational speed during the forced control, as the target rotational speed, to the controller of the fan unit when the malfunction of the fan unit is detected during the forced control.

7. A communication equipment, comprising:
a cooling fan system that comprises at least one fan unit comprising a cooling fan and a controller for controlling the cooling fan, a management unit comprising a fan control section that controls the controller of the fan unit, and a circuit directly connecting the management unit to the cooling fan so as to allow the cooling fan to be controlled directly by the fan control section,
wherein the fan control section comprises a malfunction detecting section to detect malfunction of the fan unit and a forced control section that directly controls the cooling fan and carries out a forced control to forcibly rotate the cooling fan at a higher rotational speed than that during normal operation when the malfunction detecting section detects the malfunction of the fan unit.
